(19) United States
(12) Patent Application Publication
(10) Pub. No.: US 2003/0071333 A1
(43) Pub. Date: Apr. 17, 2003

(54) Leadframe, method of manufacturing the same, and method of manufacturing a semiconductor device using the same

(75) Inventor: Hideki Matsuzawa, Nagano (JP)

Correspondence Address: ARMSTRONG,WESTERMAN & HATTORI, LLP, 1725 K STREET, NW, SUITE 1000, WASHINGTON, DC, 20006, US

(73) Assignee: SHINKO ELECTRIC INDUSTRIES CO., LTD., Nagano-shi (JP)

(21) Appl. No.: 10/260,571

(22) Filed: Oct. 1, 2002

(30) Foreign Application Priority Data
Oct. 15, 2001 (JP) 2001-317272

(51) Int. Cl. H01L 23/495

(52) U.S. Cl. 257/676; 257/666

(57) ABSTRACT

A leadframe for use in a leadless package (a semiconductor device) such as a quad flat non-leaded package (QFN) includes a base frame having a die-pad demarcated severally to correspond to each semiconductor element to be mounted thereon and a plurality of leads arranged around the corresponding die-pad, and an adhesive tape attached to the base frame so as to cover one surface side of each die-pad and the plurality of leads arranged around the corresponding die-pad. The plurality of leads corresponding to each die-pad extend with a comb shape from the corresponding die-pad to an outward direction, with being separated severally from the die-pad, inside a region to be ultimately divided into a semiconductor device. The leadframe further includes a plurality of support bars severally linked to each die-pad. The support bars are supported by the adhesive tape, and extend close to a peripheral portion of the region to be ultimately divided into the semiconductor device.

### BACKGROUND OF THE INVENTION

(a) Field of the Invention

The present invention relates to a leadframe for use in packages for mounting semiconductor elements. More specifically, the present invention relates to a leadframe which is used in a leadless package (a semiconductor device) such as a quad flat non-leaded package (QFN) and has a lead shape suitable for enhancing workability upon a dicing step after a step of sealing a package with resin, to a method of manufacturing the leadframe, and to a method of manufacturing a semiconductor device using the leadframe.

(b) Description of the Related Art

FIG. 1A and FIG. 1B schematically show a constitution of a prior art leadframe for use in a leadless package such as QFN. In the drawings, FIG. 1A shows a plan-view constitution of part of the leadframe, and FIG. 1B shows a cross-sectional structure of the leadframe viewed along B-B′ line in FIG. 1A, respectively.

In FIG. 1A and FIG. 1B, reference numeral 10 denotes part of a strip-shaped leadframe, which is basically formed of a base frame 11 obtained by etching a metal plate. This base frame 11 includes a frame structure formed by an outer frame (an outer frame portion) 12 and inner frames 13 (also referred to as “section bars”) arranged in a matrix inside the outer frame 12. In the outer frame 12, there are provided guide holes 14 to be engaged with a conveyor mechanism upon conveying the leadframe 10. In a center of an opening defined by the frames 12 and 13, there are disposed die-pads 15 on which semiconductor elements are mounted. Each of the die-pads 15 is supported and linked to the outer frame 12 by four support bars 16 extending from four corners of the corresponding frames 12 and 13. Moreover, leads 17 extend with a comb shape from the respective frames 12 and 13 toward the die-pads 15. An adhesive tape 18 is attached to a back surface of the base frame 11. Moreover, broken lines CL show dividing lines upon ultimately dividing the leadframe 10 into respective packages in an assembly process. Although it is not particularly illustrated in FIG. 1A and FIG. 1B, all the section bars (the inner frames 13) are removed upon dividing the leadframe 10 into the packages.

When the package is assembled using the leadframe 10 having the above-described constitution, the basic process thereof includes the steps of mounting semiconductor elements on the die-pads of the leadframe (die bonding), electrically connecting electrodes of the semiconductor elements to the leads of the leadframe with bonding wires (wire bonding), sealing the semiconductor elements, the bonding wires and the like with molding resin (molding), dividing the leadframe sealed with molding resin into respective packages (semiconductor devices) with a dicer or the like after peeling off the adhesive tape (dicing), and the like. Moreover, as the types of molding, there are an individual molding in which the semiconductor elements are individually sealed with resin, and a mass molding in which the semiconductor elements are sealed together with resin. Since the individual molding has a difficulty in terms of an efficient package assembly as compared to the mass molding, the mass molding has been a mainstream in recent years.

Upon dicing the leadframe 10 into packages in the assembly process of the packages such as QFNs using the above mass molding, according to the constitution of the conventional leadframe as described above, the dicer is supposed to simultaneously cut the metal (the leads 17) and the molding resin along the dividing lines CL (FIG. 1A).

However, most dicers are originally adapted for cutting resin, and accordingly, where the relatively soft resin and the metal harder than the resin are simultaneously cut, there are problems such as a rapid wear of a blade of the dicer, a slowdown in the dicing speed, and a decrease in workability as a consequence.

Moreover, since the metal (the leads 17) and the molding resin are simultaneously cut, “burrs” of metal are frequently generated on downstream sides of cutting directions of the leads 17. As a result, there is also a problem of a decrease in productivity or yield.

In addition, there is also an inconvenience in that the leads are peeled off from the resin upon stress applied by the blade of the dicer, which is attributable to a difference in hardness between the resin and the metal.

Also, it is a common practice to inspect each of the packages (semiconductor devices) prior to shipment. In the inspection prior to shipment, it is more convenient to conduct the inspection by setting the leadframe in the state before dicing on a testing instrument, rather than to conduct the inspection by serially setting the individual products divided into packages on the testing instrument. Moreover, the approach to conduct the inspection of the leadframe in the state prior to dicing is more time-saving because it is possible to inspect a lot of semiconductor devices at a time.

However, according to the constitution of the prior art leadframe (FIG. 1A), the respective leads 17 corresponding to two adjacent die-pads 15 are electrically connected to one another via the section bars 13 (in other words, the two adjacent packages are electrically connected to each other). As a result, there is an inconvenience in that the individual packages cannot be inspected before the leadframe is diced in the package assembly process.

### SUMMARY OF THE INVENTION

An object of the present invention is to provide a leadframe capable of solving inconveniences such as a generation of burrs or a detachment of leads from resin upon dicing in the assembly process of the semiconductor devices and increasing dicing workability, productivity and yield, and further capable of effectuating inspection of individual semiconductor devices prior to the dicing, and also to provide a method of manufacturing the leadframe and a method of manufacturing a semiconductor device using the leadframe.

To attain the above object, according to one aspect of the present invention, there is provided a leadframe including a base frame including a die-pad demarcated severally to correspond to each semiconductor element to be mounted thereon, and a plurality of leads arranged around the corresponding die-pad; an adhesive tape attached to said base frame so as to cover one surface side of each die-pad and the plurality of leads arranged around the corresponding die-pad; and the plurality of leads corresponding to each die-pad extending with a comb shape from the corresponding die-pad to an outward direction, with being separated severally from the die-pad, inside a region to be ultimately divided into a semiconductor device.

According to the constitution of the leadframe of this aspect, the individual leads corresponding to each die-pad exist only inside the region to be demarcated by the portion to be ultimately detached from the base frame. In other words, although metal portions (the section bars 13 in FIG. 1A) for linking the leads to one another exist on the dividing lines (the portions to be detached from the leadframe) in the prior art leadframe, such metal portions do not exist in the constitution of the leadframe according to the present invention.

Therefore, in the step of dicing the leadframe into individual packages in the assembly process of packages (semiconductor devices), there is no inconvenience in that the metal (the leads) and the molding resin have to be simultaneously cut as in the prior art. Namely, it is possible to cut only the molding resin. As a result, it is possible to suppress wear of a dicer blade, to increase a dicing speed and thereby to enhance a workability in the dicing process. These advantages contribute to an improvement in productivity and yield.

Also, since it is possible to cut only the molding resin, it is possible to remove the inconvenience encountered in the prior art such as a generation of metal “burrs” or a detachment of leads from the resin.

Furthermore, the respective leads corresponding to each die-pad exist only inside the region demarcated by the dividing lines (the portions to be detached from the leadframe). Accordingly, it is possible to resolve the state where the respective leads corresponding to two adjacent die-pads are electrically connected to one another via the metal portion (the section bar 13) such as encountered in the prior art leadframe (FIG. 1A). In other words, it is possible to achieve the state where two adjacent packages are electrically isolated from each other. As a result, it is possible to conduct inspection of individual semiconductor devices in the state prior to dicing.

Also, according to another aspect of the present invention, there is provided a method of manufacturing a leadframe, including the steps of forming a base frame having an arrangement of die-pads provided for respective semiconductor elements to be mounted thereon and a plurality of leads being linked to the corresponding die-pad and extending with a comb shape to an outward direction, by etching or stamping a metal plate; forming concave portions by half-etching at portions where said plurality of leads are linked to the corresponding die-pad, of one surface of said base frame; attaching an adhesive tape to a surface of the side on which said concave portions are formed, of said base frame; and cutting portions where said concave portions are formed, of said plurality of leads.

Also, according to a modified aspect of the method of manufacturing a leadframe of the above-described aspect, there is provided a method of manufacturing a leadframe, including the steps of forming a base frame having an arrangement of die-pads provided for respective semiconductor elements to be mounted thereon and a plurality of leads being linked to the corresponding die-pad and extending with a comb shape to an outward direction, and simultaneously forming concave portions at portions where said plurality of leads are linked to the corresponding die-pad, of one surface of said base frame, by using resists patterned into predetermined shapes on both surfaces of a metal plate and simultaneously etching the both sides of the metal plate; attaching an adhesive tape to a surface of the side on which said concave portions are formed, of said base frame; and cutting portions where said concave portions are formed, of said plurality of leads.

Furthermore, according to still another aspect of the present invention, there is provided a method of manufacturing a semiconductor device using the leadframe according to any one of the foregoing aspects. The method includes the steps of mounting semiconductor elements on the respective die-pads of the leadframe; electrically connecting electrodes of the semiconductor elements to the corresponding plurality of leads of said leadframe with bonding wires; sealing the semiconductor elements, the bonding wires and the plurality of leads with molding resin from the side of a surface where the semiconductor elements are mounted, of said leadframe; peeling off said adhesive tape; and cutting the leadframe sealed with molding resin along outer perimeters of regions severally including the plurality of leads corresponding to each die-pad so as to form respective semiconductor devices.

### BRIEF DESCRIPTION OF THE DRAWINGS

FIG. 1A and FIG. 1B are views schematically showing a constitution of a prior art leadframe;

FIG. 2A and FIG. 2B are views schematically showing a constitution of a leadframe according to one embodiment of the present invention;

FIG. 3A to FIG. 3E are cross-sectional views (partially, plan view) showing one example of a process of manufacturing the leadframe shown in FIG. 2A and FIG. 2B;

FIG. 4A to FIG. 4C are cross-sectional views showing another example of the process of manufacturing the leadframe shown in FIG. 2A and FIG. 2B;

FIG. 5 is a cross-sectional view showing one example of a semiconductor device using the leadframe shown in FIG. 2A and FIG. 2B;

FIG. 6A to FIG. 6E are cross-sectional views showing one example of a process of manufacturing the semiconductor device shown in FIG. 5; and

FIG. 7 is a plan view schematically showing a constitution of a leadframe according to another embodiment of the present invention.

### DESCRIPTION OF THE PREFERRED EMBODIMENTS

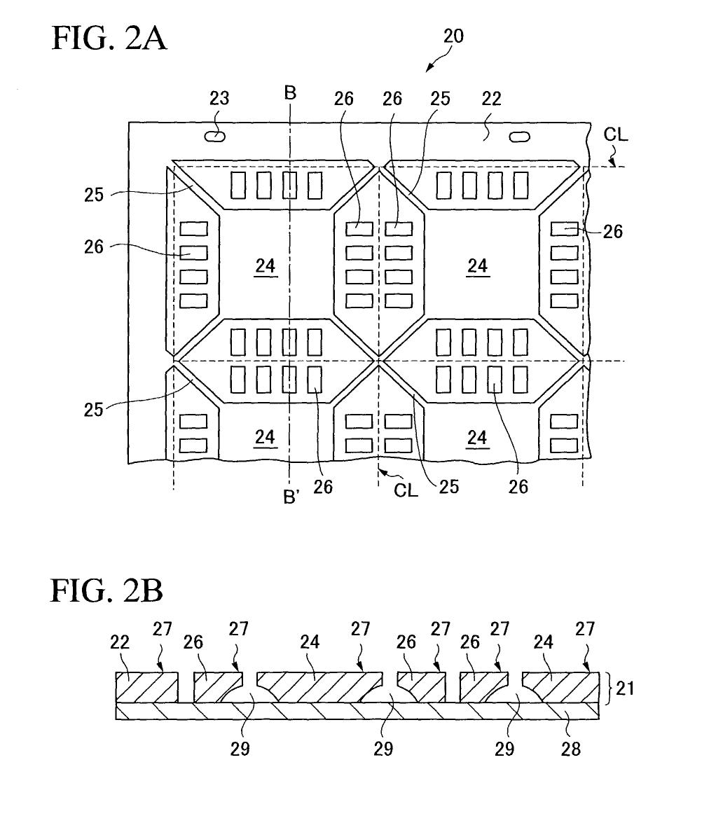

FIG. 2A and FIG. 2B schematically show a constitution of a leadframe according to one embodiment of the present invention for use in a leadless package such as QFN. In the drawings, FIG. 2A shows a plan-view constitution of part of the leadframe, and FIG. 2B shows a cross-sectional structure of the leadframe viewed along B-B′ line in FIG. 2A, respectively.

In FIG. 2A and FIG. 2B, reference numeral 20 denotes part of a strip-shaped leadframe, which is basically composed of a base frame 21 obtained by either etching or stamping a metal plate. In this base frame 21, reference numeral 22 denotes an outer frame (an outer frame portion); reference numeral 23 denotes a guide hole to be engaged with a conveyor mechanism upon conveying the leadframe 20; reference numeral 24 denotes a die-pad demarcated to correspond to each semiconductor element to be mounted thereon; reference numeral 25 denotes a support bar supporting the corresponding die-pad 24; and reference numeral 26 denotes a lead severally arranged around the corresponding die-pad 24. Here, each of the die-pads 24 is supported by the corresponding four support bars 25 and linked (connected) to the adjacent die-pad 24 via the corresponding support bars 25. Eventually, the die-pads 24 are linked (connected) to the outer frame 22 via the outermost support bars 25.

Also, a plurality of leads 26 provided for the corresponding die-pad 24 extend with a comb shape to an outward direction, inside a region (a region surrounded by broken lines in the drawing) demarcated by a portion to be detached from the base frame 21 to form an individual semiconductor device upon assembly of packages (semiconductor devices) as described later, in such a manner that the leads are severally separated from the corresponding die-pad 24. Each of the leads 26 includes an inner lead portion to be electrically connected to an electrode of the semiconductor device, and an outer lead portion (an external connection terminal) to be electrically connected to a wiring on a packaging substrate.

Moreover, a metal film 27 is formed on the entire surface of the base frame 21, and an adhesive tape 28 is adhered to a back surface (a lower surface in the illustrated example) of the base frame 21. Adhesion (taping) of the adhesive tape 28 is basically performed as a countermeasure for preventing a leakage (which is also referred to as “mold flush”) of molding resin to the back surface of the frame in a molding step (a resin sealing step). Furthermore, the adhesive tape 28 has a function of supporting the die-pads 24 and the support bars 25 together with the outer frame 22, and of supporting the respective leads 26 so as not to fall off when the leads 26 are detached from the die-pads 24 in the event of cutting predetermined portions of the respective leads 26 in the process of manufacturing the leadframe 20 as described later.

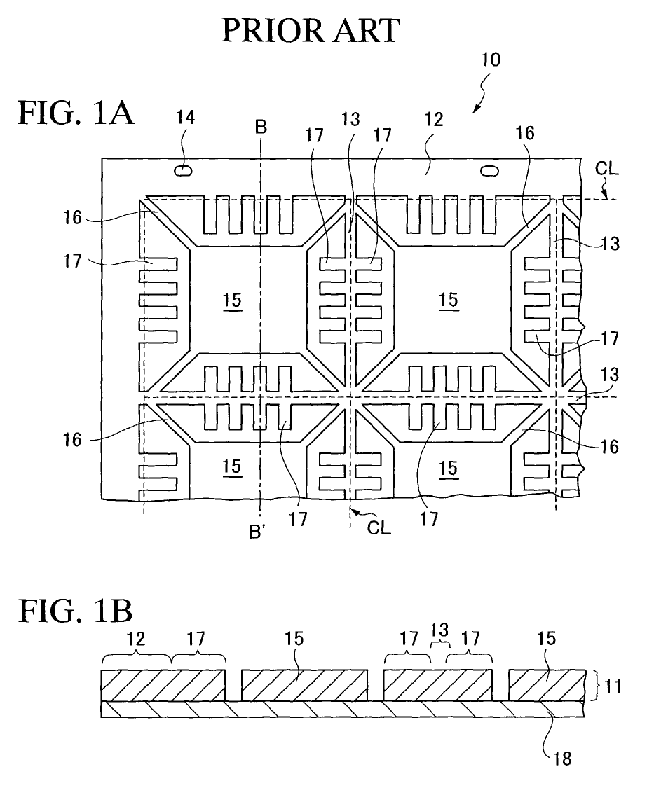

Also, reference numeral 29 denotes concave portions formed by half-etching as described later. Broken lines CL show dividing lines upon ultimately dividing the leadframe 20 into respective packages in the package assembly process, as similar to the example of FIG. 1A.

In the leadframe 10 (FIG. 1A) according to the above-described conventional example, the metal portions (the section bars 13) for linking the respective leads 17 to one another exist on the dividing lines CL. On the contrary, it is a characteristic of the leadframe 20 of this embodiment that such metal portions are eliminated therefrom. Accordingly, in the leadframe 20 of this embodiment, the adhesive tape 28 is attached to one side of the base frame 21 in order to retain locations of disposition of the leads 26 which are individually separated.

In other words, in the conventional example (FIG. 1A and FIG. 1B), a plurality of leads 17 corresponding to each die-pad 15 are linked to each of the frames (the outer frame 12 and the section bars 13), and the leads 17 extend with a comb shape from the frames toward the corresponding die-pad. On the contrary, in this embodiment (FIG. 2A and FIG. 2B), a plurality of leads 26 corresponding to each die-pad 24 extend with a comb shape from the corresponding die-pad to an outward direction, inside the region demarcated by the dividing lines CL while the leads 26 are separated from the corresponding die-pad. The constitutions of the both leadframes are different in this regard.

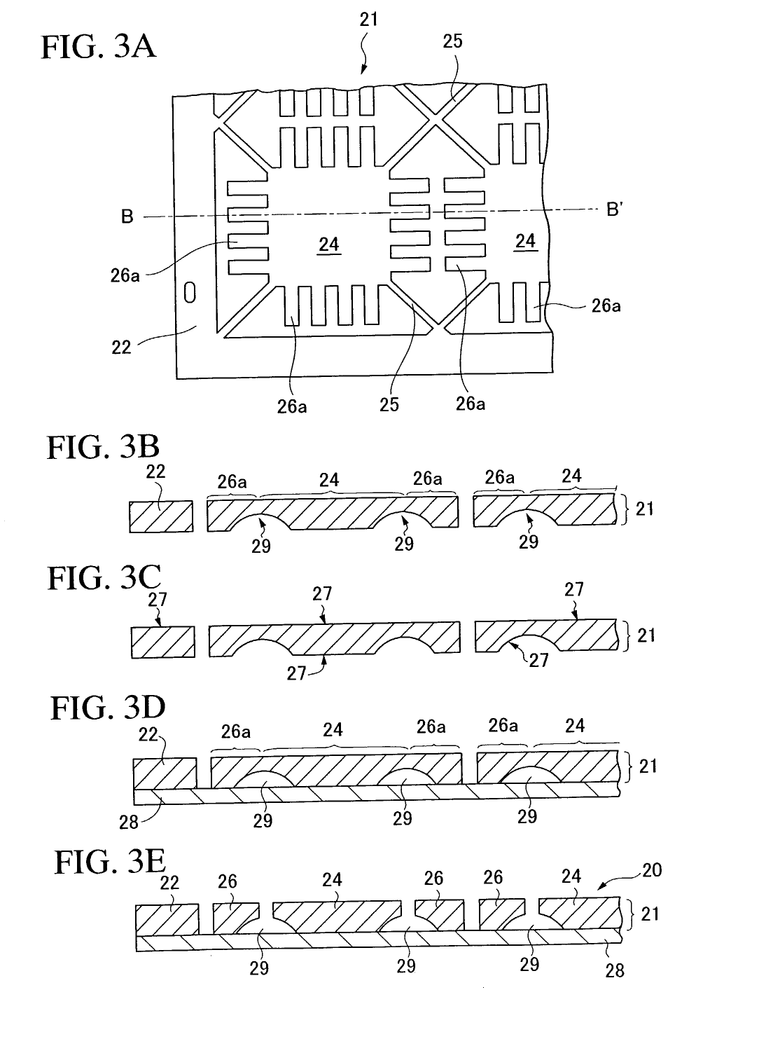

Next, description will be made regarding a method of manufacturing the leadframe 20 of this embodiment with reference to FIG. 3A to FIG. 3E collectively showing one example of the manufacturing method. In the drawings, FIG. 3B to FIG. 3E show cross-sectional structures viewed along B-B′ line in FIG. 3A.

In the first step (FIG. 3A), the base frame 21 is formed by either etching or stamping the metal plate.

As shown in the illustrated plan-view constitution, the base frame 21 to be formed in this step has a structure including the die-pads 24 for respective semiconductor elements to be mounted thereon, and an arrangement of the leads 26a being linked to the die-pads and extending with a comb shape to an outward direction. Moreover, there are arranged the support bars 25 so as to mutually link (connect) the respective die-pads 24 and the outer frame 22.

Here, for example, copper (Cu), a Cu-based alloy, iron-nickel (Fe—Ni), a Fe—Ni-based alloy, or the like is used as the material for the metal plate.

In the next step (FIG. 3B), the concave portions 29 are formed at the predetermined portions on one surface (which is a lower surface in the illustrated example) of the base frame 21 by half-etching.

In the plan-view constitution shown in FIG. 3A, positions where the leads 26a are linked to the corresponding die-pad 24 are selected as positions (predetermined portions) for forming the concave portions 29.

Here, the half-etching process can be performed, for example, by covering the entire surface of the base frame 21 except regions of the predetermined portions with a mask (not shown) and then by wet-etching the base frame 21.

In the next step (FIG. 3C), the metal film 27 is formed on the entire surface of the base frame 21 provided with the concave portions 29, by electrolytic plating.

For example, nickel (Ni) is plated on the surface of the base frame 21 for the purpose of enhancing adhesion of palladium (Pd) plating while using the base frame 21 as a feed layer, then Pd is plated on the Ni layer for the purpose of enhancing conductivity and gold (Au) flashing is further effected on the Pd layer, so as to form the metal film (Ni/Pd/Au) 27.

Note that the constitution of plating of the metal film 27 is not limited to the foregoing. For example, it is also possible to form a solder film (metal film), after sealing the leadframe with resin in a later step, on the lead portions exposed from the molding resin, by electroless plating, printing, or the like. Alternatively, other publicly-known plating constitutions are also applicable thereto.

In the next step (FIG. 3D), the adhesive tape 28 made of epoxy resin, polyimide resin or the like is attached to cover the surface of the side where the concave portions 29 are formed, of the base frame 21, i.e. the lower surface of the base frame 21.

In the last step (FIG. 3E), the portions where the concave portions 29 are formed, of the respective leads 26a (FIG.3D), are cut by stamping out, for example, with a die (a punch). In this way, the leadframe 20 (FIG. 2A and 2B) of this embodiment is fabricated.

Additionally, where the leads 26a include a lead which is to be used for a ground line or a power supply line with being linked to the die-pad, then it is not necessary to separate the lead concerned from the die-pad.

As described above, according to the leadframe 20 of this embodiment and its manufacturing method, the plurality of leads 26 corresponding to each die-pad 24 severally demarcated for the semiconductor element to be mounted exist only inside the region defined by the dividing line CL (the portion to be detached from the leadframe 20). In other words, although the metal portions (the section bars 13) for linking the respective leads to one another exist on the dividing line CL in the leadframe 10 of the conventional example (FIG. 1A and FIG. 1B), such metal portions do not exist in this embodiment.

Therefore, where packages (semiconductor devices) are assembled using the leadframe 20 of this embodiment, it is unnecessary to cut the leads 26 in the final step of dicing. Namely, it is possible to virtually cut only the molding resin. In this way, it is possible to remove the inconvenience (such as problems of a rapid wear of the dicer blade, a slowdown in the dicing speed and a decrease in workability, or inconvenience such as a generation of metal “burrs” or a detachment of leads from the resin) as encountered in the prior art. Such advantages contribute to an improvement in productivity and yield.

Also, since the leads 26 corresponding to each die-pad 24 exist only inside the region defined by the dividing line CL, the leads 26 corresponding to two adjacent die-pads 24 are electrically isolated from one another. Namely, it is possible to resolve the state as seen in the leadframe 10 (FIG. 1A and FIG. 1B) according to the conventional example, in which the respective leads 17 corresponding to two adjacent die-pads 15 are electrically connected to one another via the section bars 13. In this way, it is possible to inspect the individual packages (the semiconductor devices) at the stage prior to dicing.

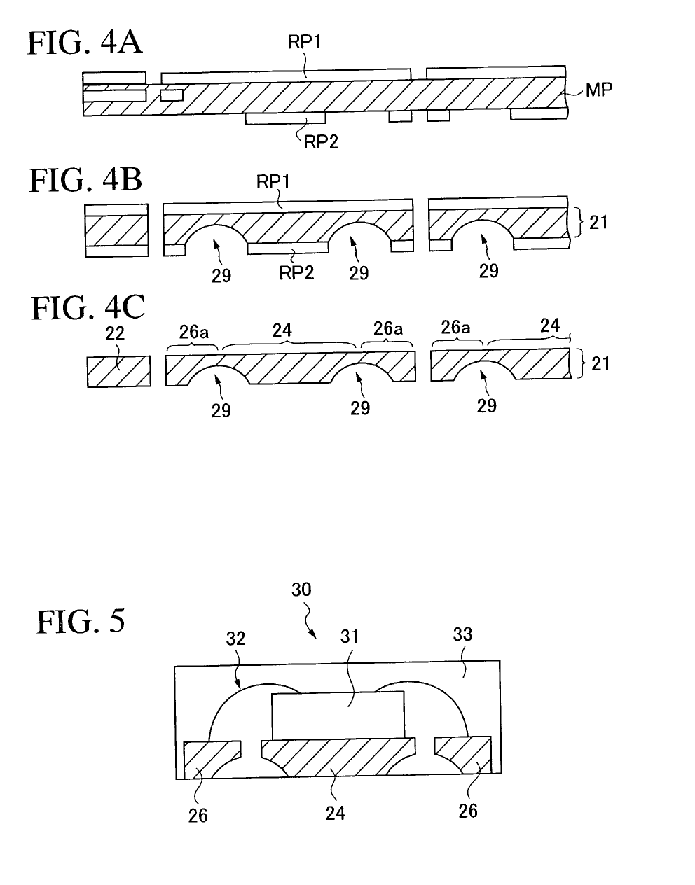

In the method of manufacturing the leadframe 20 according to the above-described embodiment, formation of the base frame 21 (FIG. 3A) and formation of the concave portions 29 (FIG. 3B) are performed in the different steps. However, it is also possible to form these constituents in one process. One example of the manufacturing process in this case is shown in FIG. 4A to FIG. 4C.

In the illustrated method, etching resists are first coated on both surfaces of a metal plate MP (a plate made of Cu or a Cu-based alloy, for example). Then, the resists are patterned using masks (not shown) which are severally patterned into predetermined shapes. In this way, resist patterns RP1 and RP2 are formed (FIG. 4A).

In this case, regarding the resist pattern RP1 on the upper side (the side where the semiconductor elements are mounted), the corresponding resist is patterned so as to cover regions on the metal plate MP corresponding to the die-pads 24, the respective leads 26a linked to the corresponding die-pad and extending in a comb shape, the support bars 25 and the outer frame 22. On the other hand, regarding the resist pattern RP2 on the lower side, the corresponding resist is patterned so as to cover regions on the metal plate MP corresponding to the die-pads 24, the respective leads 26a, the support bars 25 and the outer frame 22, and so as to expose regions corresponding to the concave portions 29.

In this way, after covering the both surfaces of the metal plate MP with the resist patterns RP1 and RP2, the pattern of the base frame 21 as shown in FIG. 3A and the concave portions 29 are simultaneously formed, for example, by wet etching (FIG. 4B).

Further, the etching resists (RP1 and RP2) are peeled off and thereby the base frame 21 of the structure as shown in FIG. 3B is obtained (FIG. 4C). The steps thereafter are the same as those shown in FIG. 3C to FIG. 3E.

According to the method shown in FIG. 4A to FIG. 4C, formation of the base frame 21 and formation of the concave portions 29 are carried out in one process. Therefore, it is possible to simplify the process as compared to the foregoing embodiment (FIG. 2A to FIG. 3E).

FIG. 5 schematically shows one example of a semiconductor device having a QFN package structure, which is fabricated using the leadframe 20 of the above-described embodiment.

In FIG. 5, reference numeral 30 denotes a semiconductor device; reference numeral 31 denotes a semiconductor element mounted on the die-pad 24; reference numeral 32 denotes a bonding wire electrically connecting each electrode of the semiconductor element 31 to the corresponding lead 26; and reference numeral 33 denotes molding resin for protecting the semiconductor element 31, the bonding wire 32, and the like.

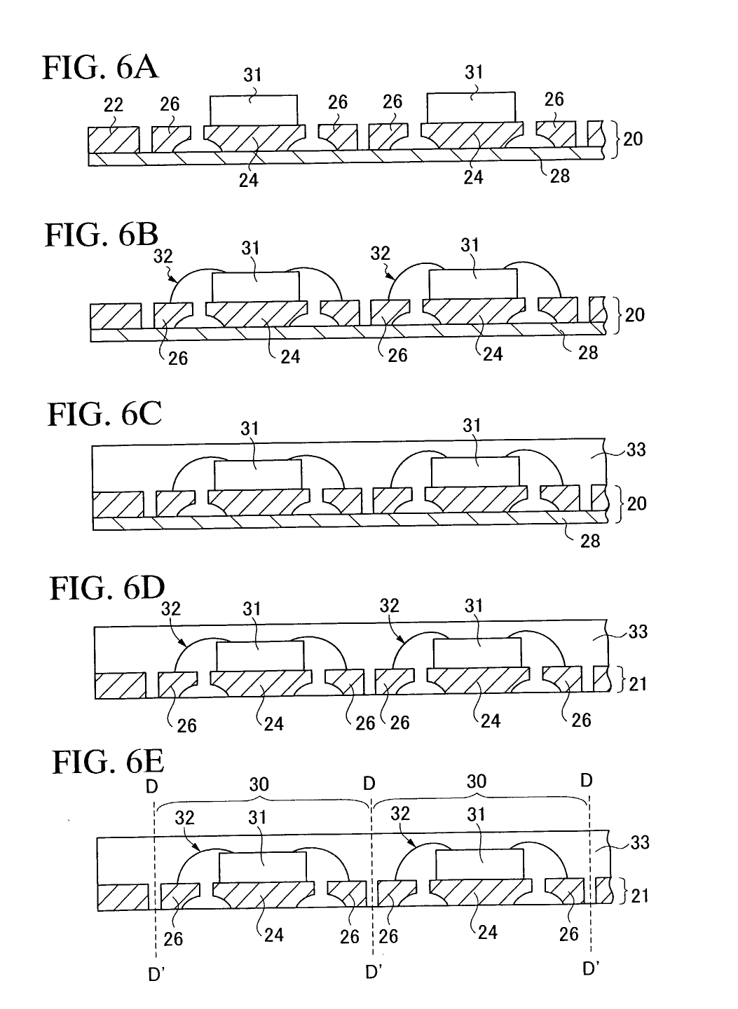

Now, description will be made regarding a method of manufacturing the semiconductor device 30 with reference to FIG. 6A to FIG. 6E collectively showing the manufacturing process thereof.

In the first step (FIG. 6A), the leadframe 20 is held with a holder jig (not shown) while putting the surface where the adhesive tape 28 is attached downward, and the semiconductor elements 31 are mounted severally on the respective die-pads 24 of the leadframe 20. To be more precise, an adhesive such as epoxy resin is coated on the die-pads 24 and bottom surfaces (opposite surfaces to the surfaces where the electrodes are formed) of the semiconductor elements 31 are set downward, whereby the semiconductor elements 31 are adhered to the die-pads 24 with the adhesive.

In the next step (FIG. 6B), the electrodes of the respective semiconductor elements 31 and the inner lead portions of the corresponding leads 26 on one surface of the leadframe 20 (which is the upper side in the illustrated example) are electrically connected to each other with the bonding wires 32 severally. In this way, the respective semiconductor elements 31 are mounted on the leadframe 20.

In the next step (FIG. 6C), the entire surface on the side where the semiconductor elements 31 are mounted, of the leadframe 20, is sealed with the molding resin 33 according to a mass molding. Although it is not particularly illustrated in the drawing, such sealing is performed by disposing the leadframe 20 on a lower molding die (a pair of upper and lower molding dies) and binding the leadframe 20 with the upper die from above, and then carrying out heat and pressure treatment while filling the molding resin 33. For example, transfer molding is used as the means for sealing.

In the next step (FIG. 6D), the leadframe 20 (FIG. 6C) sealed with the molding resin 33 is taken out of the molding dies, and then the adhesive tape 28 is peeled off and removed from the base frame 21. By peeling and removing the adhesive tape 28, the side of mounting surfaces of the semiconductor devices is exposed and thereby the leads 26 as the external connection terminals are exposed to the same plane as the molding resin 33.

In the final step (FIG. 6E), the base frame 21 (the leadframe mounting the respective semiconductor elements 31 and the entire surface thereof being sealed with the molding resin 33) is divided into package units along dividing lines D-D′ as illustrated with broken lines using a dicer or the like, such that each package unit includes one semiconductor element 31. Here, the dividing lines D-D′ are aligned with the dividing lines CL illustrated with the broken lines in FIG. 2A.

By the above steps, the semiconductor device 30 (FIG. 5) having the QFN package structure is fabricated.

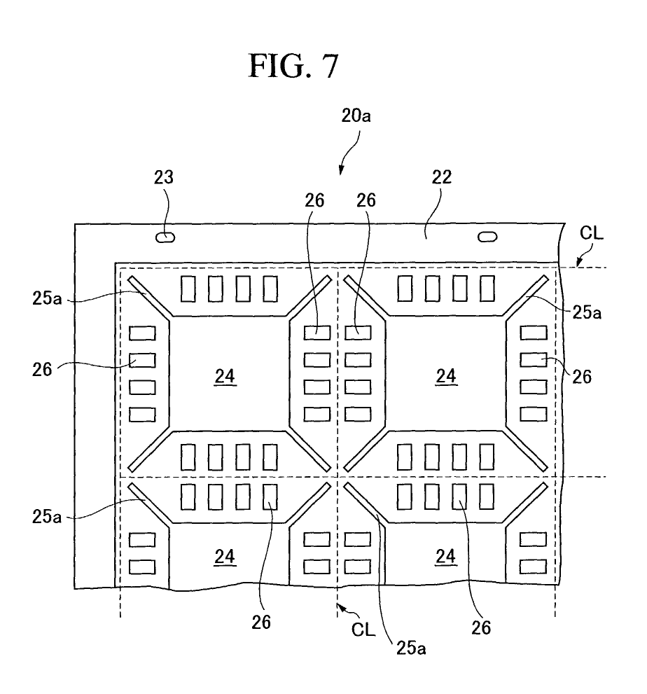

FIG. 7 schematically shows a plan-view constitution of a leadframe (in part) according to another embodiment of the present invention.

In a leadframe 20a according to this embodiment, portions of support bars 25a corresponding to respective die-pads 24, which are the portions to be detached from an outer frame 22 and other support bars bonded thereto upon cutting the leadframe 201 into respective packages (semiconductor devices), are cut away in advance. Namely, four support bars 25a corresponding to each die-pad 24 extend inside a region defined by dividing lines CL, and the support bars 25a are not linked (connected) to the adjacent die-pad 24 and its corresponding support bars 25a. In this respect, the leadframe 20a has a different structure from that of the leadframe 20 according to the embodiment shown in FIG. 2A and FIG. 2B. Since other parts of the constitution are the same as those in the embodiment shown in FIG. 2A and FIG. 2B, description thereof will be omitted.

Similarly, since a method of manufacturing the leadframe 20a is also basically the same as the manufacturing processes as shown in FIG. 3A to FIG. 3E or FIG. 4A to FIG. 4C, detailed description thereof will be omitted. Note that, according to this embodiment, in the event of forming the concave portions 29 in the respective leads 26a (FIG. 3A to FIG. 3E), additional concave portions are formed at portions of the support bars 25a corresponding to the respective die-pads 24 in positions to be detached from the leadframe 20a in the assembly process of semiconductor devices, by half-etching. Furthermore, after attaching the adhesive tape 28 (FIG. 3D), the portions of the respective support bars 25a where the concave portions are formed are simultaneously cut in the event of cutting the portions of the respective leads 26a where the concave portions 29 are formed.

In the previous embodiment (FIG. 2A to FIG. 3E), description has been made on the assumption that the support bars 25 do not concern inspection of the individual packages (the semiconductor devices) (i.e., on the assumption that the support bars 25 are not connected to any signal lines or power supply/ground lines). On the contrary, this embodiment (FIG. 7) provides the leadframe 20a, which is also applicable to the case where the support bars 25a are connected to any signal lines or power supply/ground lines.

What is claimed is:

1. A leadframe comprising:
a base frame including a die-pad demarcated severally to correspond to each semiconductor element to be mounted thereon, and a plurality of leads arranged around the corresponding die-pad;
an adhesive tape attached to said base frame so as to cover one surface side of each die-pad and the plurality of leads arranged around the corresponding die-pad; and
said plurality of leads corresponding to each die-pad extending with a comb shape from the corresponding die-pad to an outward direction, with being separated severally from the die-pad, inside a region to be ultimately divided into a semiconductor device.

2. The leadframe according to claim 1, further comprising a plurality of support bars severally linked to each die-pad, the support bars being supported by said adhesive tape, and extending close to a peripheral portion of the region to be ultimately divided into the semiconductor device.

3. The leadframe according to claim 1, wherein said plurality of leads corresponding to each die-pad are used as external connection terminals when the leadframe is ultimately divided into respective semiconductor devices, and the leads are exposed to the side of a mounting surface of the corresponding semiconductor device.

4. A method of manufacturing a leadframe, comprising the steps of:
forming a base frame having an arrangement of die-pads provided for respective semiconductor elements to be mounted thereon and a plurality of leads being linked to the corresponding die-pad and extending with a comb shape to an outward direction, by etching or stamping a metal plate;
forming concave portions by half-etching at portions where said plurality of leads are linked to the corresponding die-pad, of one surface of said base frame;
attaching an adhesive tape to a surface of the side on which said concave portions are formed, of said base frame; and
cutting portions where said concave portions are formed, of said plurality of leads.

5. The method according to claim 4, further comprising the steps of:
forming a plurality of support bars in the step of forming a base frame, in such a manner that one end of each of the support bars is linked to an outer frame portion of the base frame and another end thereof is linked to the corresponding die-pad;
forming additional concave portions in the step of forming concave portions, by half-etching from one surface side of the base frame, at portions of the respective support bars to be detached from the outer frame portion of the base frame when the leadframe is ultimately divided into respective semiconductor devices; and
cutting portions where said additional concave portions are formed, of said plurality of support bars, after the step of attaching an adhesive tape.

6. The method according to claim 4, between the step of forming concave portions and the step of attaching an adhesive tape, further comprising the step of forming a metal film on an entire surface of said base frame by electrolytic plating.

7. A method of manufacturing a leadframe, comprising the steps of:
forming a base frame having an arrangement of die-pads provided for respective semiconductor elements to be mounted thereon and a plurality of leads being linked to the corresponding die-pad and extending with a comb shape to an outward direction, and simultaneously forming concave portions at portions where said plurality of leads are linked to the corresponding die-pad, of one surface of said base frame, by using resists patterned into predetermined shapes on both surfaces of a metal plate and simultaneously etching the both sides of the metal plate;
attaching an adhesive tape to a surface of the side on which said concave portions are formed, of said base frame; and
cutting portions where said concave portions are formed, of said plurality of leads.

8. The method according to claim 7, further comprising the steps of:
forming a plurality of support bars in the step of forming a base frame, in such a manner that one end of each of the support bars is linked to an outer frame portion of the base frame and another end thereof is linked to the corresponding die-pad;
forming additional concave portions in the step of forming concave portions, by half-etching from one surface side of the base frame, at portions of the respective support bars to be detached from the outer frame portion of the base frame when the leadframe is ultimately divided into respective semiconductor devices; and
cutting portions where said additional concave portions are formed, of said plurality of support bars, after the step of attaching an adhesive tape.

9. The method according to claim 7, between the step of forming concave portions and the step of attaching an adhesive tape, further comprising the step of forming a metal film on an entire surface of said base frame by electrolytic plating.

10. A method of manufacturing a semiconductor device using the leadframe according to any one of claims 1 and 2, the method comprising the steps of:
mounting semiconductor elements on the respective die-pads of the leadframe;
electrically connecting electrodes of the semiconductor elements to the corresponding plurality of leads of said leadframe with bonding wires;
sealing the semiconductor elements, the bonding wires and the plurality of leads with molding resin from the side of a surface where the semiconductor elements are mounted, of said leadframe;
peeling off said adhesive tape; and
cutting the leadframe sealed with molding resin along outer perimeters of regions severally including the plurality of leads corresponding to each die-pad so as to form respective semiconductor devices.

11. The method according to claim 10, wherein said sealing with molding resin is performed by a mass molding in which an entire surface of the leadframe on the side where the semiconductor elements are mounted is sealed with resin.
